(19) United States
(12) Patent Application Publication
(10) Pub. No.: US 2013/0080093 A1
(43) Pub. Date: Mar. 28, 2013

(54) POWER COMPUTING APPARATUS AND METHOD

(71) Applicants: Wan Cheol Yang, Gyeonggi-do (KR); Kyung Uk Kim, Gyeonggi-do (KR)

(72) Inventors: Wan Cheol Yang, Gyeonggi-do (KR); Kyung Uk Kim, Gyeonggi-do (KR)

(73) Assignees: KOREA ELECTRIC POWER CORPORATION, Seoul (KR); SAMSUNG ELECTRO-MECHANICS CO., LTD., Suwon (KR)

(21) Appl. No.: 13/479,995

(22) Filed: May 24, 2012

(30) Foreign Application Priority Data
Sep. 27, 2011 (KR) 10-2011-0097809

(51) Int. Cl. G01R 21/133; G06F 19/00

(52) U.S. Cl. 702/60

(57) ABSTRACT

A power computing apparatus and method is provided. The power computing apparatus includes: a multiplexer configured to receive detected single-phase current and voltage signals and output a single analog signal; an analog-to-digital converter configured to convert the analog signal output from the multiplexer into a digital signal; a demultiplexer configured to separate the digital conversion signal output from the analog-to-digital converter into digital signals representing single-phase current and voltage and output the separated digital signals; a phase detector configured to detect a phase angle between the single-phase current and voltage signals; and a power computing block configured to compute power from the digital current and voltage signals output from the demultiplexer by using error compensation parameter and the phase angle detected by the phase detector.

### CROSS-REFERENCE TO RELATED APPLICATIONS

This application claims the benefit of Korean Patent Application No. 10-2011-0097809 filed with the Korea Intellectual Property Office on Sep. 27, 2011, the disclosure of which is incorporated herein by reference.

### BACKGROUND OF THE INVENTION

1. Field of the Invention

The present invention relates to a power computing apparatus and method, and more particularly, to a power computing apparatus and method using a single analog-to-digital (ND) converter.

2. Description of the Related Art

Most household appliances or office equipments operate with power. Thus, it is important to accurately measure power consumption, in addition to reducing power consumption. For accurate charging, power companies need to accurately measure the amount of electricity used by each customer.

A digital watt-hour meter computes power in a digital manner. According to the digital computation of power, a voltage and a current having an analog value are sampled and digitized, and power is computed by multiplying a voltage value by a current value. In a digital system, it is important to simultaneously sample a voltage and a current at each phase in order to accurately maintain a relative phase. Therefore, a conventional watt-hour meter is provided with an analog-to-digital (A/D) converter at a current signal channel and a voltage signal channel for each phase. The conventional watt-hour meter computes power by simultaneously converting a voltage and a current and processing the simultaneously sampled signals in a digital processor.

Therefore, in the case of computing a single-phase power, two A/D converters are required for two channels for a voltage and a current. In the case of a three-phase power, six A/D converters are required for six channels. As a result, if the number of channels increases, the number of A/D converters also increases, leading to an increase in chip size and cost. Since a plurality of channels operate at the same time, interference may occur between the channels.

In addition, as the number of ND converters increases, power consumption also increases.

To solve the above problems, there is a need for power computation technology using a single A/D converter.

### SUMMARY OF THE INVENTION

The present invention has been invented in order to overcome the above-described problems and it is, therefore, an object of the present invention to provide an apparatus and method for computing power using a single A/D converter and a phase detector.

In accordance with one aspect of the present invention to achieve the object, there is provided a power computing apparatus, which includes: a multiplexer configured to receive detected single-phase current and voltage signals and output a single analog signal; an analog-to-digital converter configured to convert the analog signal output from the multiplexer into a digital signal; a demultiplexer configured to separate the digital conversion signal output from the analog-to-digital converter into digital signals representing single-phase current and voltage and output the separated digital signals; a phase detector configured to detect a phase angle between the single-phase current and voltage signals; and a power computing block configured to compute power from the digital current and voltage signals output from the demultiplexer by using error compensation parameter and the phase angle detected by the phase detector.

The power computing block may compute the error compensation parameter by using the phase angle detected by the phase detector and a phase error caused by a sampling delay between the single-phase current and voltage signals in the multiplexer.

The power computing block may compute active power using the following equation:

VI cos θ=VI cos(θ+θₑ)+VIθₑ sin θ

where V is an effective value of the digital voltage signal, I is an effective value of the digital current signal, θ is the detected phase angle, and θₑ is the phase error caused by the sampling delay.

The power computing block may compute reactive power using the following equation:

VI sin θ=VI sin(θ+θₑ)−VIθₑ cos θ

where V is an effective value of the digital voltage signal, I is an effective value of the digital current signal, θ is the detected phase angle, and θₑ is the phase error caused by the sampling delay.

The power computing apparatus may further include a detector configured to detect the single-phase current and voltage signals.

In accordance with another aspect of the present invention to achieve the object, there is provided a power computing apparatus, which includes: a multiplexer configured to receive detected multi-phase current and voltage signals and output a single analog signal; an analog-to-digital converter configured to convert the analog signal output from the multiplexer into a digital signal; a demultiplexer configured to separate the digital conversion signal output from the analog-to-digital converter into multi-channel digital signals representing multi-phase current and voltage and output the multi-channel digital signals; each of phase detectors configured to detect phase angle between the current and voltage signals by each phase; and a power computing block configured to compute power from the digital current and voltage signals output by each phase from the demultiplexer by using error compensation parameters and the phase angles detected by the phase detectors.

The power computing block may compute the error compensation parameters by using the phase angles detected by the phase detectors and phase errors caused by sampling delays between the current and voltage signals at corresponding phases in the multiplexer.

The power computing block may compute multi-phase active power from the sum of active powers at each phase, and the active power by each phase is computed using the following equation:

VₚIₚ cos θ=VₚIₚ cos(θ+θₑ)+VₚIₚθₑ sin θ

where Vₚ is an effective value of the digital phase-voltage signal at the corresponding phase, Iₚ is an effective value of the digital phase-current signal at the corresponding phase, θ is the phase angle at the corresponding phase, θₑ is the phase error caused by the sampling delay.

The multi-phase current and voltage signals may be three-phase signals. The power computing block may compute three-phase active power from the sum of active powers at each phase. The active powers at each phase may be computed using the following equation:

$${V}_{P} {I}_{P} cos θ = {V}_{P} {I}_{P} cos ( θ + {θ}_{e} ) + {V}_{P} {I}_{P} {θ}_{e} sin θ or$$

$$\frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ$$

where Vₚ is an effective value of a digital phase-voltage signal at the corresponding phase, Iₚ is an effective value of a digital phase-current signal at the corresponding phase, V_{L} is an effective value of a digital line-voltage signal at the corresponding phase, I_{L} is an effective value of a digital line-current signal at the corresponding phase, θ is the phase angle at the corresponding phase, and θₑ is the phase error caused by the sampling delay.

The multi-phase current and voltage signals may be three-phase signals. The power computing block computes three-phase reactive power from the sum of reactive powers at each phase. The reactive powers at each phase may be computed using the following equation:

$${V}_{P} {I}_{P} sin θ = {V}_{P} {I}_{P} sin ( θ + {θ}_{e} ) - {V}_{P} {I}_{P} {θ}_{e} cos θ$$

$$or \frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ$$

where Vₚ is an effective value of a digital phase-voltage signal at the corresponding phase, Iₚ is an effective value of a digital phase-current signal at the corresponding phase, V_{L} is an effective value of a digital line-voltage at the corresponding phase, I_{L} is an effective value of a digital line-current signal at the corresponding phase, θ is the phase angle at the corresponding phase, and θₑ is the phase error caused by the sampling delay at the corresponding phase.

The power computing apparatus may further include: a detector configured to detect the multi-phase current and voltage signals.

In accordance with another aspect of the present invention to achieve the object, there is provided a power computing method, which includes: receiving and multiplexing detected single-phase current and voltage signals and outputting a single analog signal; detecting a phase angle between the single-phase current and voltage signals; converting the analog signal output in the multiplexing step into a digital signal; demultiplexing a digital conversion signal converted in the analog-to-digital converting step to separate the digital conversion signal into 2-channel digital signals representing single-phase current and voltage and output the 2-channel digital signals; and computing power from the digital current and voltage signals output in the demultiplexing step by using error compensation parameter and the phase angle detected in the phase detecting step.

The power computing step may include computing the error compensation parameter by using the phase angle detected in the phase detecting step and a phase error caused by a sampling delay between the single-phase current and voltage signals in the multiplexing step.

The power computing step may include computing active power using the following equation:

VI cos θ=VI cos(θ+θₑ)+VIθₑ sin θ,

where V is an effective value of the digital voltage signal, I is an effective value of the digital current signal, θ is the detected phase angle, and θₑ is the phase error caused by the sampling delay.

The power computing step may include computing reactive power using the following equation:

VI sin θ=VI sin(θ+θₑ)−VIθₑ cos θ

where V is an effective value of the digital voltage signal, I is an effective value of the digital current signal, θ is the detected phase angle, and θₑ is the phase error caused by the sampling delay.

In accordance with another aspect of the present invention to achieve the object, there is provided a power computing method, which includes: receiving and multiplexing detected multi-phase current and voltage signals and outputting a single analog signal; detecting phase angles between the current and voltage signals by each phase; converting the analog signal output in the multiplexing step into a digital signal; demultiplexing a digital conversion signal converted in the analog-to-digital converting step to separate the conversion digital signal into multi-channel digital signals representing multi-phase current and voltage and output the multi-channel digital signals; and computing power from the digital current and voltage signals output by each phase in the demultiplexing step by using error compensation parameters and the phase angles detected in the phase detecting step.

The power computing step may include computing the error compensation parameters by using the phase angles detected in the phase detecting step and a phase error caused by a sampling delay between the current and voltage signals at a corresponding phase in the multiplexing step.

The power computing step may include computing multi-phase active power from the sum of active powers at each phase, and the active powers at each phase may be computed using the following equation:

VₚIₚ cos θ=VₚIₚ cos(θ+θₑ)+VₚIₚθₑ sin θ

where Vₚ is an effective value of the digital phase-voltage signal at the corresponding phase, Iₚ is an effective value of the digital phase-current signal at the corresponding phase, θ is the phase angle at the corresponding phase, θₑ is the phase error caused by the sampling delay.

The multi-phase current and voltage signals may be three-phase signals. The power computing step may include computing three-phase active power from the sum of active powers at each phase. The active powers at each phase may be computed using the following equation:

$${V}_{P} {I}_{P} cos θ = {V}_{P} {I}_{P} cos ( θ + {θ}_{e} ) + {V}_{P} {I}_{P} {θ}_{e} sin θ$$

$$or \frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ$$

where Vₚ is an effective value of a digital phase-voltage signal at the corresponding phase, Iₚ is an effective value of a digital phase-current signal at the corresponding phase, V_{L} is an effective value of a digital line-voltage signal at the corresponding phase, I_{L} is an effective value of a digital line-current signal at the corresponding phase, θ is the phase angle at the corresponding phase, and θₑ is the phase error caused by the sampling delay.

The multi-phase current and voltage signals may be three-phase signals. The power computing step may include computing three-phase reactive power from the sum of reactive powers at each phase. The reactive powers at each phase may be computed using the following equation:

$${V}_{P} {I}_{P} sin θ = {V}_{P} {I}_{P} sin ( θ + {θ}_{e} ) - {V}_{P} {I}_{P} {θ}_{e} cos θ$$

$$or \frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ$$

where Vₚ is an effective value of a digital phase-voltage signal at the corresponding phase, Iₚ is an effective value of a digital phase-current signal at the corresponding phase, V_{L} is an effective value of a digital line-voltage at the corresponding phase, I_{L} is an effective value of a digital line-current signal at the corresponding phase, θ is the phase angle at the corresponding phase, and θₑ is the phase error caused by the sampling delay at the corresponding phase.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a power computing apparatus in accordance with an embodiment of the present invention;

FIG. 2 is a view schematically showing a power computing apparatus in accordance with another embodiment of the present invention;

FIG. 3 is a view schematically showing a phase error caused by a sampling delay;

FIG. 4 a graph showing active power with respect to a variation in a phase angle;

FIG. 5 is a graph showing an error with respect to a phase angle and a phase error;

FIG. 6 is a flowchart schematically showing a power computing method in accordance with another embodiment of the present invention; and

FIG. 7 is a flowchart schematically showing a power computing method in accordance with another embodiment of the present invention.

### DETAILED DESCRIPTION OF THE PREFERABLE EMBODIMENTS

Embodiments of the present invention for achieving the above objects will be described with reference to the accompanying drawings. In the specification, like reference numerals denote like elements, and duplicate or redundant descriptions will be omitted for conciseness.

It will be understood that when an element is referred to as being ‘connected to’ or ‘coupled to’ another element, it may be directly connected or coupled to the other element or at least one intervening element may be present therebetween. In contrast, when an element is referred to as being ‘directly connected to’ or ‘directly coupled to’ another element, there are no intervening element therebetween.

It should be noted that the singular forms ‘a’ ‘an’ and ‘the’ are able to be intended to include the plural forms as well, unless the context clearly indicates otherwise.

It should be understood that the terms ‘comprise’, ‘include’ and ‘have’, when used in this specification, specify the presence of stated features or elements, but do not preclude the presence or addition of one or more other features, elements, or combinations thereof.

Power computing apparatuses in accordance with first and second embodiments of the present invention will be described in detail with reference to the accompanying drawings.

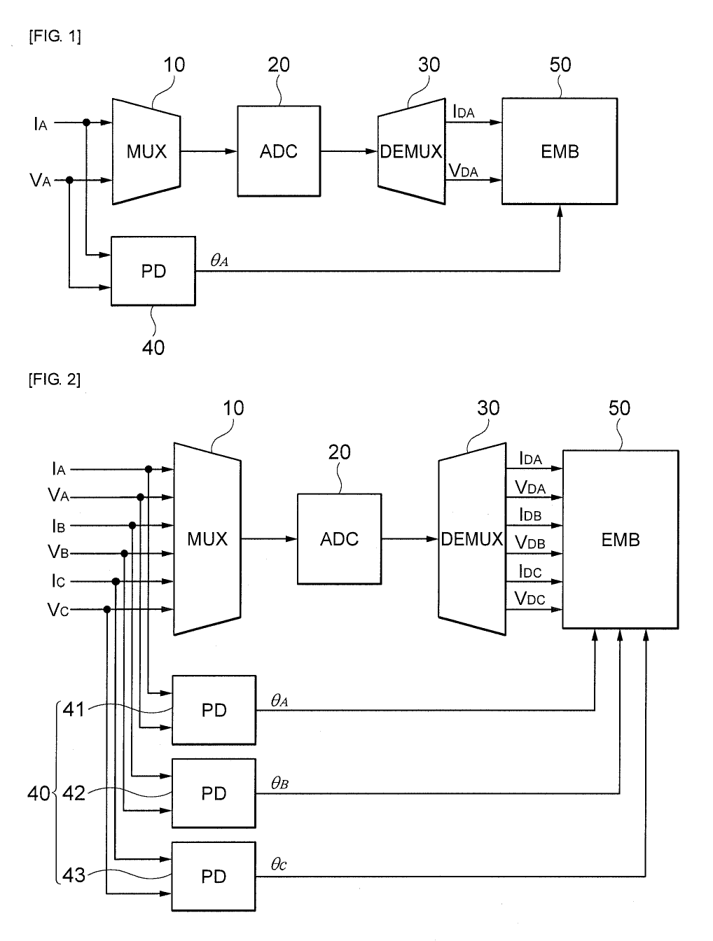

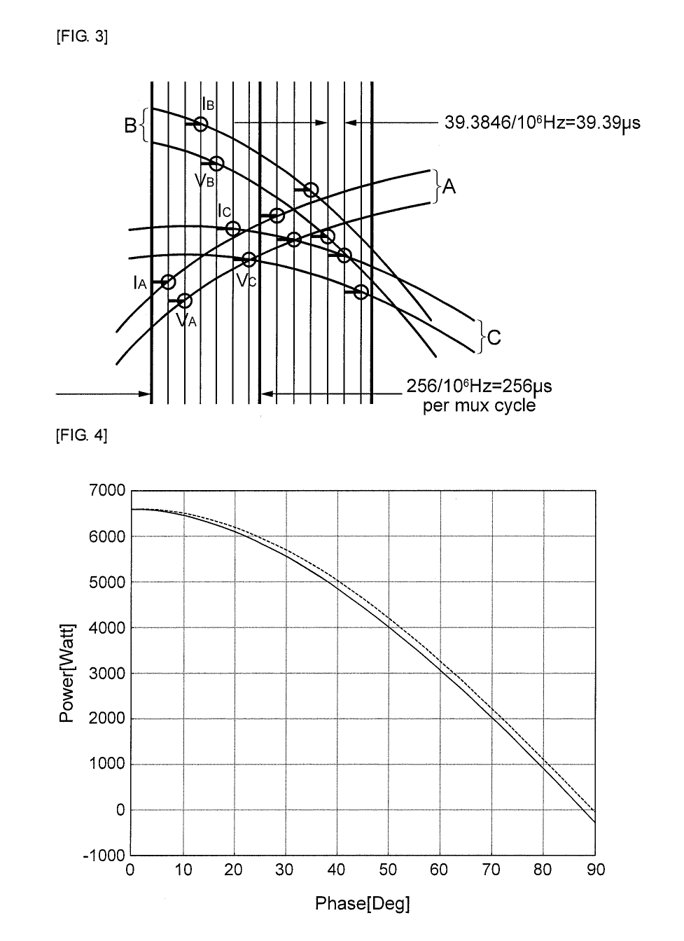

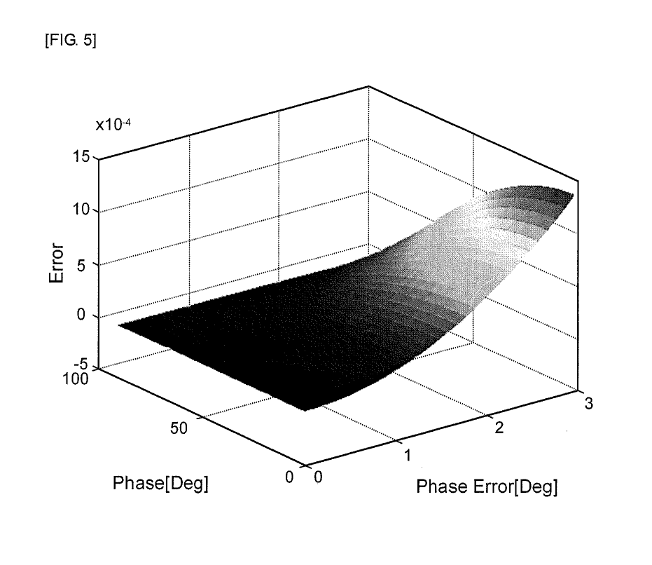

FIG. 1 is a view schematically showing a power computing apparatus in accordance with an embodiment of the present invention, and FIG. 2 is a view schematically showing a power computing apparatus in accordance with another embodiment of the present invention. FIG. 3 is a view schematically showing a phase error caused by a sampling delay. FIG. 4 a graph showing active power with respect to a variation of a phase angle, and FIG. 5 is a graph showing an error with respect to a phase angle and a phase error.

A first embodiment of the present invention will be described below with reference to FIG. 1.

Referring to FIG. 1, the power computing apparatus in accordance with the first embodiment of the present invention includes a multiplexer 10, an A/D converter 20, a demultiplexer 30, a phase detector 40, and a power computing block 50. Although not shown, the power computing apparatus may further include a detector (not shown) that detects a single-phase current signal and a single-phase voltage signal. The detector (not shown) may include a current sensor, a voltage sensor, or the like.

The multiplexer 10 receives detected single-phase current and voltage signals and outputs a single analog signal. Referring to FIG. 1, the multiplexer 10 needs to transmit a single signal to the A/D converter 20. Thus, the multiplexer 10 receives a 1-channel current signal and a 1-channel voltage signal, performs a sampling according to a preset clock, and outputs a single signal. At this time, during the multiplexing process, a delay phase error exists due to a sampling time difference between the current signal and the voltage signal according to the sampling based on the preset clock. Referring to FIG. 3, the sampling time difference between the current signal and the voltage signal is exemplified as 61.04 μs. The sampling time difference occurs due to the clock for multiplexing, and it causes a delay phase error between the current signal and the voltage signal. While the delay phase error is small when a power factor is high, the delay phase error is serious as a power factor becomes lower. Therefore, the phase error needs to be removed or corrected.

In addition, as one example, the multiplexer 10 receives a signal from a detector (not shown) that detects single-phase current and voltage signals. The single-phase current and voltage signals may be detected using a current sensor and a voltage sensor. An inherent phase delay error occurring when a current transformer (CT) sensor is used as a current sensor may be removed by correction or calibration before multiplexing in the multiplexer 10.

The A/D converter 20 of FIG. 1 converts an analog signal output from the multiplexer 10 into a digital signal. Since the A/D conversion is a well-known technology, a detailed description thereof will be omitted.

The demultiplexer 30 of FIG. 1 demultiplexes the digital conversion signal output from the A/D converter 20 to separate the digital conversion into digital signals representing single-phase current and voltage and output the digital signals. By using the multiplexer 10 and the demultiplexer 30, power may be computed using only one A/D converter 20.

In addition, the phase detector 40 of FIG. 1 detects a phase angle between the single-phase current signal and the single-phase voltage signal. In FIG. 1, θ_{A} represents a phase angle. Instead of using a plurality of A/D converters 20, the phase detector 40 is used and power is computed by applying an error compensation parameter. Since the size of the phase detector 40 is smaller than that of the A/D converter 20, the size of the power computing apparatus may be reduced. Since the phase detector 40 is commonly known, a detailed description thereof will be omitted.

The power computing block 50 of FIG. 1 computes power from the digital current and voltage signals generated from the demultiplexer 30 by using the error compensation parameter and the phase angle detected by the phase detector 40. The error compensation parameter is used to compensate the phase error caused by the sampling delay during the multiplexing. In FIGS. 1 and 2, the power computing block 50 is an energy measuring block (EMB).

The power computing block 50 will be described below in more detail. In accordance with an embodiment of the present invention, the power computing block 50 calculates an error compensation parameter by using the phase angle detected by the phase detector 40 and the phase error caused by the sampling delay between the single-phase current and voltage signals in the multiplexer 10.

Active power is computed as follows.

$$\begin{matrix}P = VI cos ( θ + {θ}_{e} ) \\ = VI ( cos θ cos {θ}_{e} - sin θ sin {θ}_{e} ) \\ \approx VI ( cos θ - {θ}_{e} sin θ ) ,\end{matrix}$$

$$where , \\ {θ}_{e} << 5° , cos {θ}_{e} \approx 1 , and sin {θ}_{e} \approx {θ}_{e} = VI cos θ - VI {θ}_{e} sin θ$$

Since θₑ<<5°, approximately, VI cos θ=VI cos(θ+θₑ)+VIθₑ sin θ. P represents active power computed from digital voltage and current values before phase error correction, and VIθₑ sin θ represents an error compensation parameter.

Likewise, reactive power may be computed as follows.

$$\begin{matrix}Q = VI sin ( θ + {θ}_{e} ) \\ = VI ( sin θ cos {θ}_{e} + cos θ sin {θ}_{e} ) \\ \approx VI ( cos θ - {θ}_{e} sin θ )\end{matrix}$$

$$where$$

$${θ}_{e} << 5° , cos {θ}_{e} \approx 1 , and sin {θ}_{e} \approx {θ}_{e} = VI sin θ + VI {θ}_{e} cos θ$$

Since θₑ<<5°, approximately, VI sin θ=VI sin(θ+θₑ)−VIθₑ cos θ. Q represents reactive power computed from digital voltage and current values before phase error correction, and VIθₑ cos θ represents an error compensation parameter.

As another example, the power computing block 50 may compute active power using VI cos θ=VI cos(θ+θₑ)+VIθₑ sin θ.

As another example, the power computing block 50 may compute reactive power using VI sin θ=VI sin(θ+θₑ)−VIθₑ cos θ.

In the above-described equations for computing active power and reactive power, V is an effective value of the digital voltage signal, I is an effective value of the digital current signal, θ represents the detected phase angle, and θₑ represents the phase error caused by the sampling delay.

Next, a second embodiment of the present invention will be described below with reference to FIG. 2. Referring to FIG. 2, the power computing apparatus includes an A/D converter 20, a demultiplexer 30, a plurality of phase detectors 40, and a power computing block 50. Although not shown, the power computing apparatus may further include a detector (not shown) that detects multi-phase current and voltage signals. The detector (not shown) may include a current sensor and a voltage sensor.

Referring to FIG. 2, the multiplexer 10 receives detected multi-phase current and voltage signals and outputs a single analog signal. The multi-phase current and voltage signals may be three-phase signals. For example, in the case of the three-phase signal, six-channel signals are input to the multiplexer 10 through three current channels and three voltage channels. Since the multiplexer 10 needs to transmit a single signal to the ND converter 20, the multiplexer 10 samples the input signals according to a set clock and outputs a single signal. At this time, during the multiplexing process, a delay phase error exists due to a sampling time difference between the current signal and the voltage signal at each phase according to the sampling based on the preset clock. Referring to FIG. 3, the sampling time difference between the current signal and the voltage signal is exemplified as 61.04 μs. The sampling time difference of 39.39 has occurs between the current and voltage signals at A, B and C phases due to the clock for a multiplexing cycle. In FIG. 3, the cycle interval of the multiplexer 10 is exemplified as 256/106 Hz=256 μs. The cycle interval is defined by the clock for sampling. The sampling time difference causes a delay phase error between the current signal and the voltage signal at each phase. While the delay phase error is small when a power factor is high, the delay phase error is serious as a power factor becomes lower. Therefore, the phase error needs to be removed or corrected.

In addition, as one example, the multiplexer 10 receives a signal from a detector (not shown) that detects multi-phase current and voltage signals. The detector may include a current sensor or a voltage sensor. An inherent phase delay error occurring when a current transformer (CT) sensor is used as a current sensor may be removed by correction or calibration before multiplexing in the multiplexer 10.

Like in FIG. 1, the ND converter 20 of FIG. 2 converts the analog signal output from the multiplexer 10 into a digital signal.

The demultiplexer 30 of FIG. 2 demultiplexes the digital conversion signal output from the A/D converter 20 to separate the digital conversion signal into multi-channel digital signals representing multi-phase current and voltage and output the multi-channel digital signals. By using the multiplexer 10 and the demultiplexer 30, power may be computed using only one A/D converter 20.

Referring to FIG. 2, the plurality of phase detectors 40 detect phase angles between the current and voltage signals at each phase. For example, in the case of a three-phase signal, three phase detectors 41, 42 and 43 are provided to detect phase angles between the current and voltage signals at three phases. In FIG. 2, θ_{A}, θ_{B}, and θ_{C} represent the phase angles at each phase.

Next, the power computing block 50 of FIG. 2 computes power from the digital current and voltage signals generated at each phase from the demultiplexer 30 by using the error compensation parameters and the phase angles detected by the phase detector 40. The error compensation parameters are used to compensate the phase error caused by the sampling delay during the multiplexing.

Next, the power computing block 50 will be described below in more detail. In accordance with an embodiment of the present invention, the power computing block 50 may calculate error compensation parameters using the phase angles detected at each phase by the phase detector 40 and the phase error caused by the sampling delay between the current and voltage signals at the corresponding phase in the multiplexer 10. The process of computing the active power and the reactive power at each phase is substantially identical to the process of computing the active power and the reactive power in the previous embodiment.

In addition, as one example, the power computing block 50 computes multi-phase active power from the sum of active powers at each phase. The active powers at each phase may be computed using VₚIₚ cos θ=VₚIₚ cos(θ+θₑ)+VₚIₚθₑ sin θ. In this case, the error compensation parameter at each phase may be VₚIₚθₑ sin θ.

As another example, in the case where the multi-phase current and voltage signals are three-phase signals, the power computing block 50 may compute three-phase active power from the sum of active powers at each phase. In this case, the active powers at each phase may be computed using VₚIₚ cos θ=VₚIₚ cos(θ+θₑ)+VₚIₚθₑ sin θ or

$$\frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ . \\ {V}_{p} {I}_{p} {θ}_{e} sin θ and \frac{1}{\sqrt{3}} {V}_{L} {I}_{L} {θ}_{e} sin θ$$

may be error compensation parameters.

Furthermore, as another example, the power computing block 50 may compute three-phase reactive power from the sum of reactive powers at each phase. In this case, the reactive powers at each phase may be computed using VₚIₚ sin θ=VₚIₚ sin(θ+θₑ)−VₚIₚθₑ cos θ or

$$\frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ . \\ {V}_{p} {I}_{p} {θ}_{e} cos θ and \frac{1}{\sqrt{3}} {V}_{L} {I}_{L} {θ}_{e} cos θ$$

may be error compensation parameters.

In the equations for computing the active power and the reactive power as described in the above embodiment, Vₚ is an effective value of the digital phase-voltage signal at the corresponding phase, and Iₚ is an effective value of the digital phase-current signal at the corresponding phase. In addition, V_{L} is an effective value of the digital line-voltage signal at the corresponding phase, and I_{L} is an effective value of the digital line-current signal at the corresponding phase.

FIG. 4 a graph showing active power according to a variation in a phase angle, and FIG. 5 is a graph showing an error according to a phase angle and a phase error.

FIG. 4 shows active power according to a variation in the phase angle in the case where the effective voltage value was 220 V, the effective current value was 30 A, and the phase angle varied in the range of 0-90°. It was assumed that the phase error caused by the sampling delay was 2.5°. A dotted graph represents the case that the active power is VI cos(θ+θₑ)+VIθₑ sin θ. The active power is almost identical to the nominal active power of VI cos θ and therefore it is overlapped with the nominal active power. A solid line represents a value of VI cos(θ+θₑ), which is the active power before correction.

FIG. 5 shows the error according to the phase error, Err=[cos θ−{cos(θ+θₑ)+θₑ sin θ}], in the case where the phase angle varied in the range of 0-90° and the phase error caused by the sampling delay was 0-3°. As can be seen from FIG. 5, as the phase angle is smaller, that is, the power factor is lower, the error caused by the phase error increases.

Next, power computing methods in accordance with third and fourth embodiments of the present invention will be described in detail with reference to the accompanying drawings. In addition, the following description will be made with reference to the above-described embodiments of the power computing apparatuses and FIGS. 1 to 5, and redundant descriptions will be omitted.

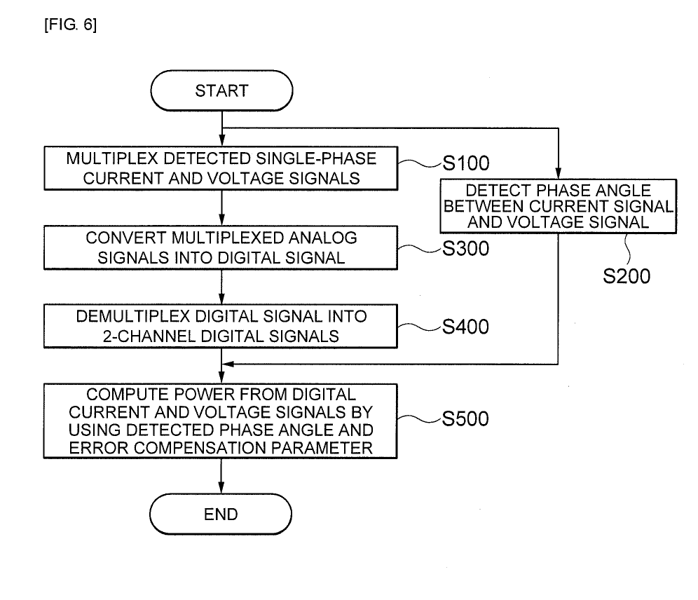

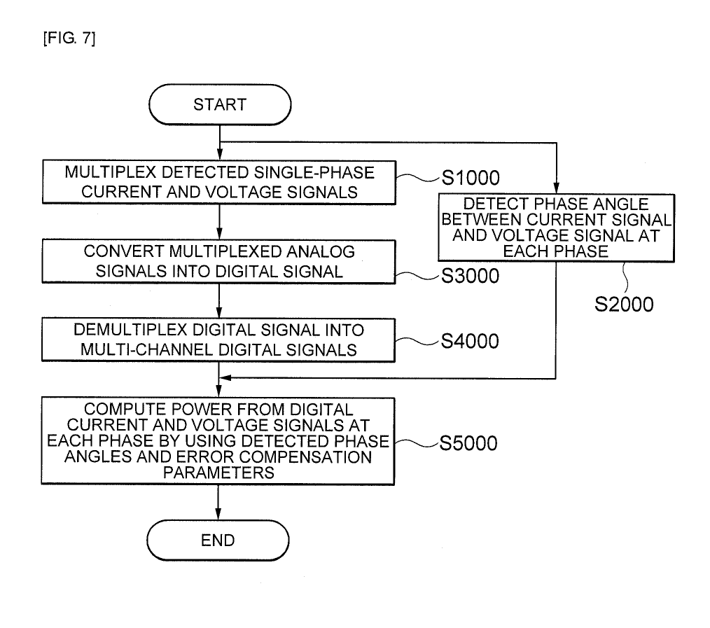

FIG. 6 is a flowchart schematically showing a power computing method in accordance with another embodiment of the present invention, and FIG. 7 is a flowchart schematically showing a power computing method in accordance with another embodiment of the present invention.

First, the third embodiment of the present invention will be described below in detail. Referring to FIG. 6, the power computing method includes a multiplexing step S100, a phase detecting step S200, an A/D converting step S300, a demultiplexing step S400, and a power computing step S500.

Referring to FIG. 6, in the multiplexing step S100, detected single-phase current and voltage signals are received, multiplexed and output as a single analog signal. Referring to FIG. 1, a 1-channel current signal and a 1-channel voltage signal are received and output as a single analog signal. In the multiplexing step S100, a single signal is output by sampling 2-channel signals according to a preset clock. Therefore, a delay phase error exists due to a sampling time difference between the current signal and the voltage signal. The delay phase error generates a significant error as a power factor is lower. Therefore, there is a need for removing or correcting the phase error.

Next, in the phase detecting step S200 of FIG. 6, a phase angle between a single-phase current signal and a single-phase voltage signal is detected.

Next, in the A/D converting step S300 of FIG. 6, the analog signal output in the multiplexing step S100 is converted into a digital signal.

Next, in the demultiplexing step S400 of FIG. 6, the digital conversion signal converted in the A/D converting step S300 is demultiplexed into 2-channel digital signals representing single-phase current and voltage to be separated into 2-channel digital signals and be output.

Next, in the power computing step S500 of FIG. 6, power is computed from the digital current and voltage signals output in the demultiplexing step S400 by using error compensation parameter and the phase angle detected in the phase detecting step S200. The error compensation parameter is used to compensate the phase error caused by the sampling delay during the multiplexing step S100.

The power computing step will be described in more detail. As one example, in the power computing step S500, the error compensation parameter may be calculated using the phase angle detected in the phase detecting step S200 and the phase error caused by the sampling delay between the single-phase current and voltage signals in the multiplexing step S100.

In addition, as another example, in the power computing step S500, active power may be computed using VI cos θ=VI cos(θ+θₑ)+VIθₑ sin θ. In this case, VIθₑ sin θ may be the error compensation parameter.

Furthermore, in the power computing step S500, reactive power may be computed using VI sin θ=VI sin(θ+θₑ)−VIθₑ cos θ.

In the above-described equations for computing the active power and the reactive power, V is an effective value of the digital voltage signal, I is an effective value of the digital current signal, θ represents the detected phase angle, and θₑ represents the phase error caused by the sampling delay.

Next, the power computing method in accordance with the fourth embodiment of the present invention will be described in detail with reference to FIG. 7. Referring to FIG. 7, the power computing method includes a multiplexing step S1000, a phase detecting step S2000, an A/D converting step S3000, a demultiplexing step S4000, and a power computing step S5000.

Referring to FIG. 7, in the multiplexing step S1000, detected multi-phase current and voltage signals are received, multiplexed and output as a single analog signal. As one example, the multi-phase current and voltage signals may be three-phase signals. In the case of the three-phase signal, 3-channel current signals and 3-channel voltage signals are received and output as a single analog signal. In the multiplexing step S1000, a single signal is output by sampling the multi-phase signals according to a preset clock. Therefore, a delay phase error exists due to a sampling time difference between the current signal and the voltage signal at each phase. The delay phase error generates a significant error as a power factor is lower. Therefore, there is a need for removing or correcting the phase error.

Next, in the phase detecting step S2000 of FIG. 7, a phase angle between the current signal and the voltage signal at each phase is detected. As illustrated in FIG. 2, a plurality of phase detectors 40 are used. In the case of the three-phase signal, three phase detectors 40 may be used.

Next, in the A/D converting step S3000 of FIG. 7, the analog signal output in the multiplexing step S1000 is converted into a digital signal.

Next, in the demultiplexing step S4000 of FIG. 7, the digital conversion signal converted in the A/D converting step S3000 is demultiplexed into multi-channel digital signals representing multi-phase current and voltage to be separated into multi-channel digital signals and be output.

Next, in the power computing step S5000 of FIG. 7, power is computed from the digital current and voltage signals output by each phase in the demultiplexing step S4000 by using error compensation parameters and the phase angles detected in the phase detecting step S2000. The error compensation parameter is used to compensate the phase error caused by the sampling delay during the multiplexing step S1000.

The power computing step will be described in more detail. As one example, in the power computing step S5000, the error compensation parameters may be calculated using the phase angles detected at each phase in the phase detecting step S2000 and the phase error caused by the sampling delay between the current and voltage signals at the corresponding phase in the multiplexing step S100.

In addition, as another example, in the power computing step S5000, multi-phase active power may be computed from the sum of active powers at each phase. The active powers at each phase may be computed using VₚIₚ cos θ=VₚIₚ cos(θ+θₑ)+VₚIₚθₑ sin θ. In this case, the error compensation parameters at each phase may be VₚIₚθₑ sin θ.

As another example, in the case where the multi-phase current and voltage signals are three-phase signals, the three-phase active power may be computed from the sum of active powers at each phase in the power computing step S5000. At this time, the active power at each phase may be computed using VₚIₚ cos θ=VₚIₚ cos(θ+θₑ)+VₚIₚθₑ sin θ or

$$\frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ . \\ {V}_{P} {I}_{P} {θ}_{e} sin θ and \frac{1}{\sqrt{3}} {V}_{L} {I}_{L} {θ}_{e} sin θ$$

may be the error compensation parameters.

Furthermore, as another example, the multi-phase current and voltage signals are three-phase signals, and three-phase reactive power may be computed from the sum of reactive powers at each phase in the power computing step S5000. In this case, the reactive power at each phase may be computed using VₚIₚ sin θ=VₚIₚ sin(θ+θₑ)−VₚIₚθₑ cos θ or

$$\frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ . \\ {V}_{P} {I}_{P} {θ}_{e} cos θ and \frac{1}{\sqrt{3}} {V}_{L} {I}_{L} {θ}_{e} cos θ$$

may be the error compensation parameters.

In the above-described equations for computing the active power and the reactive power, Vₚ is an effective value of the digital phase-voltage signal at the corresponding phase, and Iₚ is an effective value of the digital phase-current signal at the corresponding phase. V_{L} is an effective value of the digital line-voltage signal at the corresponding phase, I_{L} is an effective value of the digital line-current signal at the corresponding phase, θ is the phase angle at the corresponding phase, θₑ is the phase error caused by the sampling delay at the corresponding phase.

The embodiments of the present invention provide the power computing apparatus and method using the single A/D converter and the phase detector. Therefore, the chip size and cost may be reduced.

Moreover, since the single A/D converter is used, interference between channels in the multi-phase multi-channel system may be reduced.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A power computing apparatus, which comprises:
a multiplexer configured to receive detected single-phase current and voltage signals and output a single analog signal;
an analog-to-digital converter configured to convert the analog signal output from the multiplexer into a digital signal;
a demultiplexer configured to separate the digital conversion signal output from the analog-to-digital converter into digital signals representing single-phase current and voltage and output the separated digital signals;
a phase detector configured to detect a phase angle between the single-phase current and voltage signals; and
a power computing block configured to compute power from the digital current and voltage signals output from the demultiplexer by using error compensation parameter and the phase angle detected by the phase detector.

2. The power computing apparatus according to claim 1, wherein the power computing block computes the error compensation parameter by using the phase angle detected by the phase detector and a phase error caused by a sampling delay between the single-phase current and voltage signals in the multiplexer.

3. The power computing apparatus according to claim 2, wherein the power computing block computes active power using the following equation:
VI cos θ=VI cos(θ+θₑ)+VIθₑ sin θ
where V is an effective value of the digital voltage signal, I is an effective value of the digital current signal, θ is the detected phase angle, and θₑ is the phase error caused by the sampling delay.

4. The power computing apparatus according to claim 2, wherein the power computing block computes reactive power using the following equation:
VI sin θ=VI sin(θ+θₑ)−VIθₑ cos θ
where V is an effective value of the digital voltage signal, I is an effective value of the digital current signal, θ is the detected phase angle, and θₑ is the phase error caused by the sampling delay.

5. The power computing apparatus according to claim 1, further comprising a detector configured to detect the single-phase current and voltage signals.

6. A power computing apparatus, which comprises:
a multiplexer configured to receive detected multi-phase current and voltage signals and output a single analog signal;
an analog-to-digital converter configured to convert the analog signal output from the multiplexer into a digital signal;
a demultiplexer configured to separate the digital conversion signal output from the analog-to-digital converter into multi-channel digital signals representing multi-phase current and voltage and output the multi-channel digital signals;
each of phase detectors configured to detect phase angle between the current and voltage signals by each phase; and
a power computing block configured to compute power from the digital current and voltage signals output by each phase from the demultiplexer by using error compensation parameters and the phase angles detected by the phase detectors.

7. The power computing apparatus according to claim 6, wherein the power computing block computes the error compensation parameters by using the phase angles detected by the phase detectors and phase errors caused by sampling delays between the current and voltage signals at corresponding phases in the multiplexer.

8. The power computing apparatus according to claim 7, wherein the power computing block computes multi-phase active power from the sum of active powers at each phase, and the active power by each phase is computed using the following equation:
VₚIₚ cos θ=VₚI^{p} cos(θ+θₑ)+VₚIₚθₑ sin θ
where Vₚ is an effective value of a digital phase-voltage signal at the corresponding phase, Iₚ is an effective value of a digital phase-current signal at the corresponding phase, θ is the phase angle at the corresponding phase, θₑ is the phase error caused by the sampling delay.

9. The power computing apparatus according to claim 7, wherein:
the multi-phase current and voltage signals are three-phase signals;
the power computing block computes three-phase active power from the sum of active powers at each phase; and
the active power by each phase is computed using the following equation:
VₚIₚ cos θ=VₚIₚ cos(θ+θₑ)+VₚIₚθₑ sin θ
$${V}_{P} {I}_{P} cos θ = {V}_{P} {I}_{P} cos ( θ + {θ}_{e} ) + {V}_{P} {I}_{P} {θ}_{e} sin θ$$
$$or \frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ$$
where Vₚ is an effective value of a digital phase-voltage signal at the corresponding phase, Iₚ is an effective value of a digital phase-current signal at the corresponding phase, V_{L} is an effective value of a digital line-voltage signal at the corresponding phase, I_{L} is an effective value of a digital line-current signal at the corresponding phase, θ is the phase angle at the corresponding phase, and θₑ is the phase error caused by the sampling delay.

10. The power computing apparatus according to claim 7, wherein:
the multi-phase current and voltage signals are three-phase signals;
the power computing block computes three-phase reactive power from the sum of reactive powers at each phase; and
the reactive power by each phase is computed using the following equation:
VₚIₚ sin θ=VₚIₚ sin(θ+θₑ)−VₚIₚθₑ cos θ
$${V}_{P} {I}_{P} sin θ = {V}_{P} {I}_{P} sin ( θ + {θ}_{e} ) - {V}_{P} {I}_{P} {θ}_{e} cos θ$$
$$or \frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ$$
where Vₚ is an effective value of a digital phase-voltage signal at the corresponding phase, Iₚ is an effective value of a digital phase-current signal at the corresponding phase, V_{L} is an effective value of a digital line-voltage at the corresponding phase, I_{L} is an effective value of a digital line-current signal at the corresponding phase, θ is the phase angle at the corresponding phase, and θₑ is the phase error caused by the sampling delay at the corresponding phase.

11. The power computing apparatus according to claim 6, which further comprises:
a detector configured to detect the multi-phase current and voltage signals.

12. A power computing method, which comprises:
receiving and multiplexing detected single-phase current and voltage signals and outputting a single analog signal;
detecting a phase angle between the single-phase current and voltage signals;
converting the analog signal output in the multiplexing step into a digital signal;
demultiplexing a digital conversion signal converted in the analog-to-digital converting step to separate the digital conversion signal into 2-channel digital signals representing single-phase current and voltage and output the 2-channel digital signals; and
computing power from the digital current and voltage signals output in the demultiplexing step by using error compensation parameter and the phase angle detected in the phase detecting step.

13. The power computing method according to claim 12, wherein the power computing step comprises computing the error compensation parameter by using the phase angle detected in the phase detecting step and a phase error caused by a sampling delay between the single-phase current and voltage signals in the multiplexing step.

14. The power computing method according to claim 13, wherein the power computing step comprises computing active power using the following equation:
VI cos θ=VI cos(θ+θₑ)+VIθₑ sin θ,
where V is an effective value of the digital voltage signal, I is an effective value of the digital current signal, θ is the detected phase angle, and θₑ is the phase error caused by the sampling delay.

15. The power computing method according to claim 13, wherein the power computing step comprises computing reactive power using the following equation:
VI sin θ=VI sin(θ+θₑ)−VIθₑ cos θ
where V is an effective value of the digital voltage signal, I is an effective value of the digital current signal, θ is the detected phase angle, and θₑ is the phase error caused by the sampling delay.

16. A power computing method, which comprises:
receiving and multiplexing detected multi-phase current and voltage signals and outputting a single analog signal;
detecting phase angles between the current and voltage signals by each phase;
converting the analog signal output in the multiplexing step into a digital signal;
demultiplexing a digital conversion signal converted in the analog-to-digital converting step to separate the conversion digital signal into multi-channel digital signals representing multi-phase current and voltage and output the multi-channel digital signals; and
computing power from the digital current and voltage signals output by each phase in the demultiplexing step by using error compensation parameters and the phase angles detected in the phase detecting step.

17. The power computing method according to claim 16, wherein the power computing step comprises computing the error compensation parameters by using the phase angles detected in the phase detecting step and a phase error caused by a sampling delay between the current and voltage signals at a corresponding phase in the multiplexing step.

18. The power computing method according to claim 17, wherein the power computing step comprises computing multi-phase active power from the sum of active powers at each phase, and the active power by each phase is computed using the following equation:
VₚIₚ cos θ=VₚIₚ cos(θ+θₑ)+VₚIₚθₑ sin θ
where Vₚ is an effective value of the digital phase-voltage signal at the corresponding phase, Iₚ is an effective value of the digital phase-current signal at the corresponding phase, θ is the phase angle at the corresponding phase, θₑ is the phase error caused by the sampling delay.

19. The power computing method according to claim 17, wherein:
the multi-phase current and voltage signals are three-phase signals;
the power computing step comprises computing three-phase active power from the sum of active powers at each phase; and
the active power by each phase is computed using the following equation:
$${V}_{P} {I}_{P} cos θ = {V}_{P} {I}_{P} cos ( θ + {θ}_{e} ) + {V}_{P} {I}_{P} {θ}_{e} sin θ$$
$$or \frac{1}{\sqrt{3}} {V}_{L} {I}_{L} cos θ = \frac{1}{\sqrt{3}} {V}_{L} {I}_{L} cos ( θ + {θ}_{e} ) + \frac{1}{\sqrt{3}} {V}_{L} {I}_{L} {θ}_{e} sin θ$$
where Vₚ is an effective value of a digital phase-voltage signal at the corresponding phase, Iₚ is an effective value of a digital phase-current signal at the corresponding phase, V_{L} is an effective value of a digital line-voltage signal at the corresponding phase, I_{L} is an effective value of a digital line-current signal at the corresponding phase, θ is the phase angle at the corresponding phase, and θₑ is the phase error caused by the sampling delay.

20. The power computing method according to claim 17, wherein:
the multi-phase current and voltage signals are three-phase signals;
the power computing step comprises computing three-phase reactive power from the sum of reactive powers at each phase; and
the reactive power by each phase is computed using the following equation:
$${V}_{P} {I}_{P} sin θ = {V}_{P} {I}_{P} sin ( θ + {θ}_{e} ) - {V}_{P} {I}_{P} {θ}_{e} cos θ$$
$$or \frac{1}{\sqrt{3}} {V}_{L} {I}_{L} sin θ = \frac{1}{\sqrt{3}} {V}_{L} {I}_{L} sin ( θ + {θ}_{e} ) - \frac{1}{\sqrt{3}} {V}_{L} {I}_{L} {θ}_{e} cos θ$$
where Vₚ is an effective value of a digital phase-voltage signal at the corresponding phase, Iₚ is an effective value of a digital phase-current signal at the corresponding phase, V_{L} is an effective value of a digital line-voltage at the corresponding phase, I_{L} is an effective value of a digital line-current signal at the corresponding phase, θ is the phase angle at the corresponding phase, and θₑ is the phase error caused by the sampling delay at the corresponding phase.
